(19) United States
(12) Patent Application Publication
(10) Pub. No.: US 2016/0302311 A1
(43) Pub. Date: Oct. 13, 2016

(54) FABRICATION OF A FLEXIBLE METAL-CLAD LAMINATE

(71) Applicants: POMIRAN METALIZATION RESEARCH CO., LTD., Pingzhen (TW); TAIMIDE TECHNOLOGY INCORPORATION, Xinpu Township (TW); ARAKAWA CHEMICAL INDUSTRIES, LTD., Osaka (JP)

(72) Inventors: Chung-Yi Chen, Pingzhen City (TW); Akihisa Hamazawa, Osaka (JP); Wen-Chin Chen, Pingzhen City (TW); Chien-Feng Chiu, Pingzhen City (TW); Shih-Cheng Fan, Pingzhen City (TW)

(21) Appl. No.: 15/094,945

(22) Filed: Apr. 8, 2016

(30) Foreign Application Priority Data
Apr. 9, 2015 (TW) 104111386

(51) Int. Cl. H05K 3/10; B05D 3/00; H05K 1/09; H05K 3/00; H05K 1/02; H05K 1/03

(52) U.S. Cl. CPC H05K 3/10; H05K 1/028; H05K 1/0296; H05K 1/0346; H05K 1/0393; H05K 1/09; H05K 3/0067; B05D 3/002; H05K 2201/0154; H05K 2201/051; B05D 2201/02; B05D 2350/30; B05D 2401/40

(57) ABSTRACT

The present disclosure relates, according to some embodiments, to a method of fabricating a flexible metal-clad laminate comprising forming a metal layer on a surface of a polyimide film, wherein the metal layer and the polyimide film are contacting each other and forming a laminate, and heating the laminate at a temperature of about 80° C. to about 140° C. until a weight loss of the laminate reaches about 1% or higher.

### CROSS-REFERENCE TO RELATED APPLICATION(S)

This application claims priority to Taiwan Patent Application No. 104111386 filed on Apr. 9, 2015, the disclosure of which is incorporated herein by reference.

### FIELD OF THE DISCLOSURE

The present application relates, in some embodiments, to a method of fabricating a flexible metal-clad laminate, and, in some embodiments, to a method of fabricating a flexible metal-clad laminate having a polyimide film as a base substrate.

### BACKGROUND OF THE DISCLOSURE

A flexible copper-clad laminate (FCCL) is generally used as a circuit substrate in the electronic industry. A flexible copper-clad laminate includes a polyimide film on which is deposited a copper layer. The copper-clad laminate may also include a nickel layer interposed between the copper layer and the polyimide film. The nickel layer can serve as a barrier to prevent diffusion of the copper into the polyimide film, and provide a well contact with the polyimide film.

During a thermal treatment (such as soldering for forming a circuit), the polyimide film usually expands and deforms owing to its hygroscopicity, which may cause the formation of gaps between the polyimide film and the metal layer and consequently reduce interlayer adhesion. While some approaches have proposed to employ dual nickel plating for addressing this issue, interlayer adhesion still remains unstable.

Some known approaches also propose to apply a plasma or short wavelength UV light as a surface treatment to the polyimide film prior to the formation of the copper layer, which is aimed to increase the yield of the metal formation. However, this surface treatment adversely increases the manufacture cost. In addition, a laminate processed with the aforementioned surface treatment may exhibit deteriorated adhesion and film peeling during subsequent thermal treatment (such as soldering).

Therefore, there is a need for an improved process that can fabricate a metal-clad laminate in a cost-effective manner and address at least the foregoing issues.

### SUMMARY

The present disclosure relates, according to some embodiments, to a method of fabricating a flexible metal-clad laminate, the method comprising forming a metal layer on a surface of a polyimide film, a metal layer and a polyimide film contacting with each other and forming a laminate, and heating a laminate at a temperature between about 80° C. and about 140° C. until a weight loss of a laminate reaches about 1% or higher.

According to some embodiments, the present disclosure relates to a method of fabricating a flexible metal-clad laminate, the method comprising forming a metal layer on a surface of a polyimide film according to a roll-to-roll processing technique, the metal layer and the polyimide film contacting with each other and forming a rolled laminate, loosening the rolled laminate to form gaps between adjacent coils in the rolled laminate, and heating the rolled laminate at a temperature between about 80° C. and about 140° C. until a weight loss of the rolled laminate reaches about 1% or higher.

### BRIEF DESCRIPTION OF THE DRAWINGS

FIG. 1A illustrates a flexible metal clad laminate including a polyimide film and two metal layers stacked on a surface of the polyimide film according to a specific example embodiment of the disclosure;

FIG. 1B illustrates a flexible metal clad laminate including a polyimide film and metal layers respectively stacked on two opposite surfaces of the polyimide film according to a specific example embodiment of the disclosure;

FIG. 1C illustrates a flexible metal clad laminate including a polyimide film and metal layers stacked on one surface of the polyimide film according to a specific example embodiment of the disclosure;

FIG. 1D illustrates a flexible metal-clad laminate including a polyimide film provided with a microvia and metal layers filling in the microvia of the polyimide film according to a specific example embodiment of the disclosure;

FIGS. 2A and 2B illustrates schematic perspectives and planar views of a rolled laminate before a loosening treatment according to a specific example embodiment of the disclosure;

FIGS. 2C and 2D illustrate schematic perspectives and planar views of a laminate after a loosening treatment according to a specific example embodiment of the disclosure; and

FIG. 3 illustrates a flowchart of method steps performed in the fabrication of a flexible metal-clad laminate according to a specific example embodiment of the disclosure.

### DETAILED DESCRIPTION OF THE EMBODIMENTS

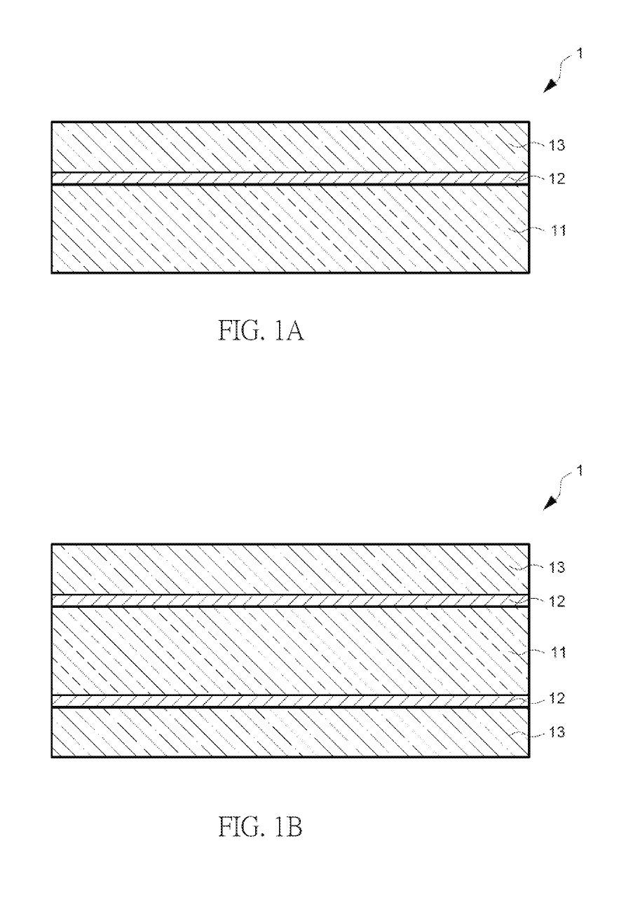

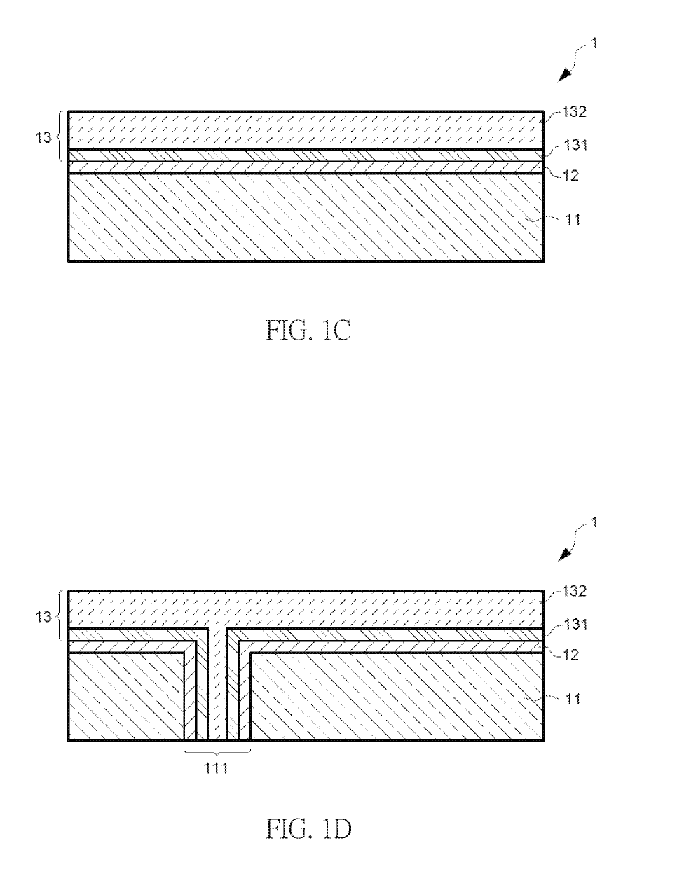

The present disclosure relates, in some embodiments, to a flexible metal-clad laminate that may include a polyimide film as a substrate. A single metal layer or a plurality of metal layers may be formed on a polyimide film. According to some embodiments, a metal layer(s) may comprise nickel, copper and combinations thereof. Referring to FIG. 1A, some embodiments may comprise a flexible metal-clad laminate 1, a polyimide film 11, a nickel layer 12 that may be formed on one surface of the polyimide film 11, and a copper layer 13 that may be formed on one surface of the nickel layer 12 opposite to the polyimide film 11. Referring to FIG. 1B, some embodiments, may comprise a flexible metal clad laminate 1′ where a nickel layer 1 and a copper layer 13 may be formed on two opposite surfaces of a polyimide film 11.

According to some embodiments, a polyimide film may comprise various monomers, which may be used to form polyimide film 11 of a flexible metal clad laminate described herein. In some embodiments, a polyimide film 11 may have a thickness between about 7 μm and about 50 μm.

According to some embodiments, a processing method may comprise forming a metal layer (e.g., nickel layer 12 as shown in FIG. 1A) on a surface of a polyimide film 11, wherein the metal layer may be in contact with the polyimide film. A polyimide film may be subjected to a surface treatment before forming a metal layer. According to some embodiments, surface treatment steps may comprise alkali surface modifications, charge adjustments, catalyst treatments, activating treatments and combinations thereof. In some embodiments, a surface treatment may include applying an alkali metal solution to a polyimide film followed with a catalyst treatment. In some embodiments, a nickel layer 12 may be formed on a treated surface by electroless plating.

In some embodiments, the present disclosure relates to a step of alkali surface modification, wherein a polyimide film may be immersed in a basic metal solution. In some embodiments, a basic metal solution may be sprayed on a polyimide film. Basic metal solution may comprise sodium hydroxide, potassium hydroxide, an aqueous solution of alkaline earth metal, ammonium hydroxide, an aqueous solution of organic amine, or any mixture thereof.

According to some embodiments, the present disclosure relates to a step of catalyst and activating treatment, wherein a polyimide film may be immersed in tin dichloride (SnCl₂) and then in a hydrochloric acid solution of palladium chloride (PdCl₂). According to some embodiments, a polyimide film may be immersed in a palladium/tin gel solution and then activated by sulfuric acid or hydrochloric acid. In some embodiments, immersing a polyimide film in a palladium/tin gel solution and then activating with sulfuric acid or hydrochloric acid may allow a formation of palladium catalyst on the surface of the polyimide film for the subsequent electroless plating.

According to some embodiments, after completion of a surface treatment, electroless plating may be performed to form a nickel layer 12 on a treated surface(s) of a polyimide film. The electroless plating may be performed with any suitable chemical reagents and parameters (i.e., concentration, temperature, reaction time and the like), which may vary according to a plating bath. In some embodiments, nickel plating may be performed by a using a bath comprising nickel-phosphorus (Ni—P), nickel-boron (Ni—B), and Ni solely. In other embodiments, nickel plating may be performed by using a bath of Ni—P, wherein the Ni—P comprises a low phosphorous content nickel. According to some embodiments, a bath of Ni—P comprises less than 5 wt % phosphorus. In some embodiments, a nickel layer comprises about 2 wt % to about 4 wt % of a phosphorous content.

In some embodiments, the present disclosure relates to nickel plating that may be applied to form a single nickel layer on at least one surface of a polyimide film, or two nickel layers on two opposite surfaces of a polyimide film. In some embodiments, a nickel layer may be formed as a single metal layer on a polyimide film. According to some embodiments, a nickel layer thickness is about 0.05 μm to about 0.15 μm. In some embodiments, a nickel layer thickness comprises about 0.05 μm, about 0.07 μm, about 0.1 μm, about 0.13 μm, about 0.14 μm, and about 0.15 μm. In some embodiments, more than one nickel layers may be formed on two opposite surfaces of a polyimide film.

According to some embodiments, the combined thickness of more than one nickel layers (i.e., sum of the thickness of two nickel layers on two opposite sides of the polyimide film) comprises a range of about 0.1 μm to about 0.3 μm. In some embodiments, a sum of the thickness of more than one nickel layers comprises a range between about 0.15 and about 0.3 μm, and about 0.15 and to about 0.28 μm.

According to some embodiments, fabrication of a flexible metal-clad laminate may comprise a so-called “roll-to-roll” processing technique. A roll-to-roll processing technique is generally used to manufacture flexible thin films in a continuous production line. In a roll-to-roll processing technique, a polyimide film may be pulled out from a cylindrical roll, processed to form a laminate including a metal layer (e.g., nickel) in contact with a surface of the polyimide film, and the laminate then is collected and wound to form a cylindrical roll. In some embodiments, prior to a thermal treatment, a roll of a laminate may undergo a loosening treatment to form gaps between adjacent coils of a rolled laminate.

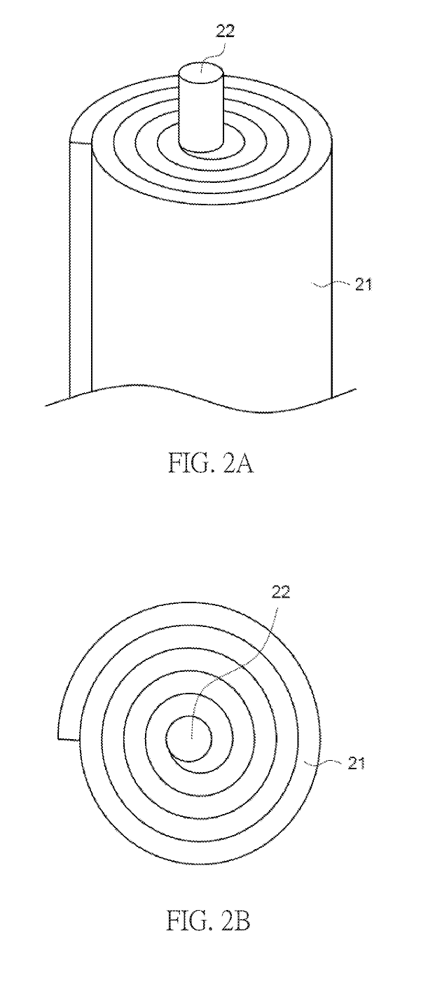

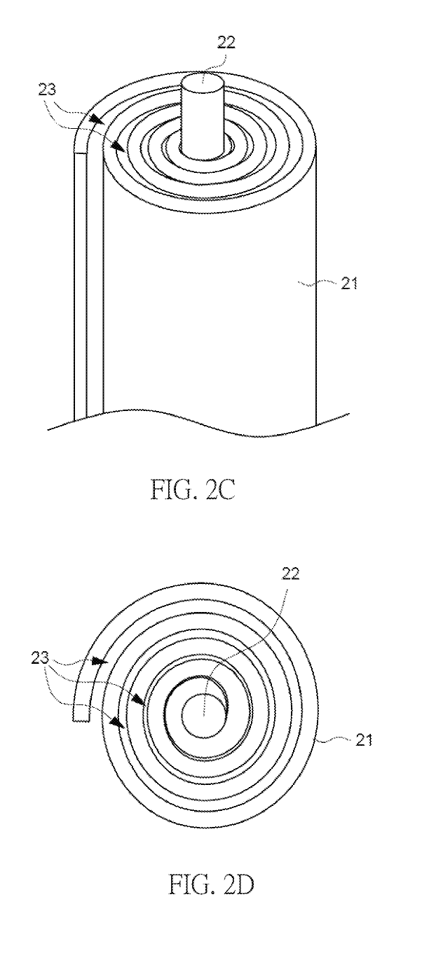

FIGS. 2A and 2B illustrate schematic views of a roll of laminate 21 before a loosening treatment. A laminate 21 may wind around an axle 22, and adjacent coils of the rolled laminate 21 may be in close contact with each other with almost no gap there between. FIGS. 2C and 2D are schematic views illustrating a roll of the laminate 21 after loosening treatment. A laminate 21 may still be wound around the axle 22, but air gaps 23 may be formed between adjacent coils in the roll of the laminate 21. In some embodiments, a roll of a laminate 21 may be looser. A loosening treatment may facilitate uniform heating of a rolled laminate in a following thermal treatment step, which may reduce or prevent differential heating of a polyimide film between a proximal region of the rolled laminate closer to a center axle and a distant region of the rolled laminate farther from the center axle.

According to some embodiments, applying a thermal treatment on a rolled laminate 21 after formation of a metal layer may improve adhesion (i.e., peel strength) between the metal layer (e.g., the nickel layer 12 as shown in FIG. 1A) and a polyimide film. A thermal treatment may maintain the peel strength between a metal layer and a polyimide film, enhance the yield of copper plating, improve its operability, or a combination thereof.

In some embodiments, the present disclosure relates to a thermal treatment, wherein a rolled laminate 21 may be heated at a temperature between about 80° C. to about 140° C. According to some embodiments, a rolled laminate 21 may be heated at a temperature comprising about 80° C., about 90° C., about 100° C., about 110° C., about 120° C., about 130° C., or any intermediate values between above these values. In some embodiments, a temperature of a thermal treatment comprises about 90° C. to about 130° C. In some embodiments, a temperature of a thermal treatment comprises a range from about 100° C. to about 120° C.

A thermal treatment may be performed continuously from about 2 hours to about 28 hours. In some embodiments, a thermal treatment may be performed for times comprising about 4 hours, about 8 hours, about 12 hours, about 16 hours, about 20 hours, about 24 hours, about 26 hours, or any intermediate values between any of the aforementioned values. In some embodiments, a thermal treatment may be performed continuously for about 12 to about 24 hours.

According to some embodiments, once a thermal treatment is completed, a laminate comprised of the polyimide film and the nickel layers formed thereon may be tested for detecting a weight loss, which may be represented by a ratio of the laminate weight loss after the thermal treatment to the laminate weight before the thermal treatment. In some embodiments, a laminate comprises a weight loss of about 1%. A laminate may comprise a weight loss of greater than about 1%. In some embodiments, a laminate may comprise a weight loss between about 1% to about 2%.

In some embodiments, a thermal treatment may help to maintain a peel strength retention between a metal layer and a polyimide film, wherein the peel strength retention may be defined with the following equation:

Peel strength retention (%)=(P1/P0)×100%,

wherein P0 is an initial peel strength before the thermal treatment, and P1 is a peel strength after completion of the thermal treatment and an aging treatment. According to some embodiments, a thermal treatment may comprise a temperature of about 150° C. In some embodiments, an aging treatment comprises about 168 hours. In some embodiments, a peel strength retention is about 50% or higher. A peel strength retention comprises about 55%, about 60%, about 65%, about 70%, about 75%, or any intermediate values between any of the aforementioned values. In some embodiments, after completion of a thermal treatment, a second metal layer may be formed on a first metal layer. In some embodiments, a second metal layer comprises a copper layer.

Electroplating may be performed to form a copper layer on a thermally treated laminate. An electroless plating step for forming a copper layer may be performed with any suitable chemical reagents and parameters (such as concentration, temperature, reaction time and the like), which may vary according to plating bath composition.

Referring to FIG. 1C, a copper layer 13 formed on a nickel layer 12 may include a first copper sublayer 131 and a second copper sublayer 132. In some embodiments, a first copper sublayer 131 is formed on a nickel layer 12 by a first electroplating. In some embodiment, in a first electroplating, a plating solution comprises a high-acid low-copper solution, the high-acid low-copper solution comprising about 200 g/L H₂SO₄, about 55 g/L CuSO₄ and about 50 ppm chloride ion. In some embodiments, a current density of about 1.5 ASD (ampere per square decimeter) may be applied to a first plating bath to form a first copper sublayer 131 on a nickel layer 12, the first copper sublayer having a thickness of about 0.67 μm. In some embodiments, a second copper sublayer 132 may formed on a first copper sublayer 131 with a second electroplating. In a second electroplating, a plating solution comprises a low-acid high-copper solution, the low-acid high-copper solution comprising about 150 g/L H₂SO₄, about 120 g/L CuSO₄ and about 50 ppm chloride ion. In some embodiments, a current density of about 2 ASD may be applied to a second plating bath to form a second copper sublayer 132 on a first copper sublayer 131, the second copper sublayer 132 having a thickness of about 2.33 μm.

In some embodiments, a thickness ratio of a first copper sublayer 131 to a sum of a thickness of the first copper sublayer 131 and a second copper sublayer 132 is 20% or higher.\.

Referring to FIG. 1D, According to some embodiments the polyimide film 11 comprises a plurality of microvias. In some embodiments, a nickel layer 12, a first copper sublayer 131 and a second copper sublayer 132 can fill a microvia 111 in a polyimide film 11. In some embodiments, a flexible metal-clad laminate containing the microvia may have enhanced flexibility.

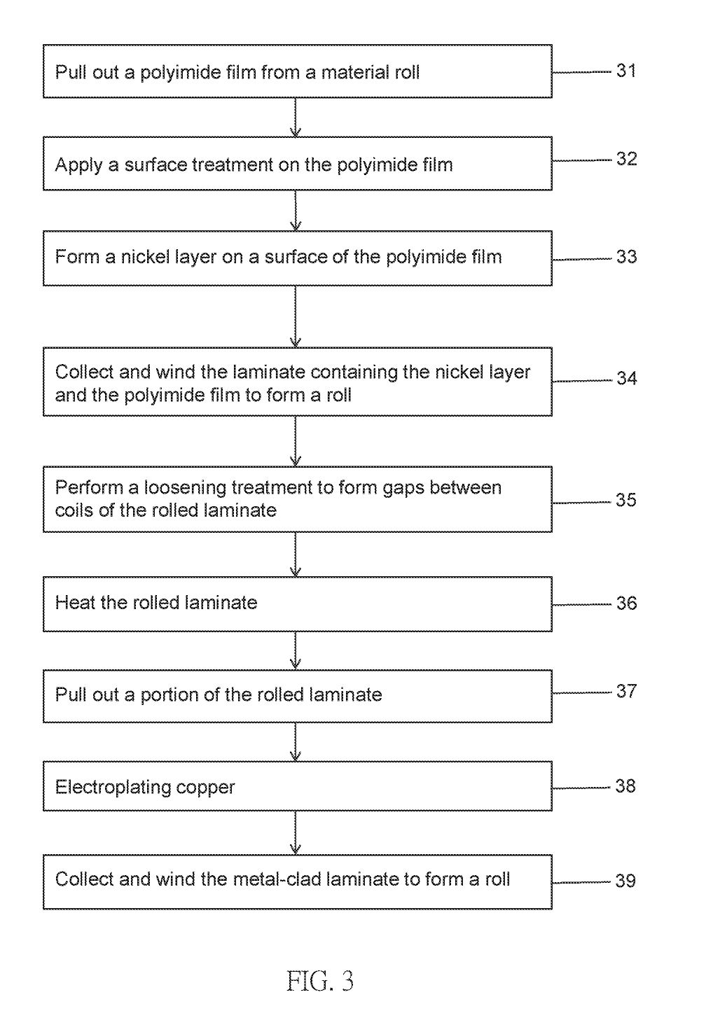

FIG. 3 illustrates a flowchart of method steps that, according to some embodiments, may fabricate a flexible metal-clad laminate comprising a polyimide film, a nickel metal layer and a copper metal layer. In some embodiments, fabricating a flexible metal-clad laminate may comprise steps 31, 32, 33, 34, 35, 36, 37, 38, 39, or combinations thereof. In some embodiments, a method may comprise step 31, wherein a polyimide film is pulled out from a material roll, step 32, wherein a surface treatment may be applied to an unrolled portion of the polyimide film, wherein Step 32 may be optional. Some embodiments comprise step 33, wherein a nickel metal layer may be formed on a surface of a polyimide film, the nickel metal layer being in contact with the polyimide film. A nickel metal layer may be formed by electroless plating. Some embodiment comprise step 34, wherein a laminate comprised of the nickel metal layer and a polyimide film may be collected and wound to form a roll, step 35, wherein a roll of a laminate may be loosened to form gaps between adjacent coils in the roll of the laminate. Some embodiments comprise step 36, wherein a loosened roll of a laminate then may be heated, and a rolled laminate may be placed in an vertically upright position while undergoing a thermal treatment. Some embodiments comprise step 37, wherein a portion of the laminate may be pulled out from the roll, and step 38, wherein electroplating may be applied on the unrolled portion of the laminate to form a copper layer thereon. Some embodiments comprise step 39, wherein a laminate comprising a polyimide film, nickel and copper metal layers may be collected and wound to form another roll.

According to some embodiments, a flexible metal-clad laminate formed comprises good thermal stability, anti-peeling property, aging resistance, no foam, no crack or wrinkle, or a combination thereof.

As will be understood by those skilled in the art who have the benefit of the instant disclosure, other equivalent or alternative compositions, systems, and methods for sanitizing a food product with regard to at least one microorganism without substantial residue on the composition left on the sanitized food product can be envisioned without departing from the description contained herein. Accordingly, the manner of carrying out the disclosure as shown and described is to be construed as illustrative only.

Persons skilled in the art may make various changes in the shape, size, number, and/or arrangement of parts without departing from the scope of the instant disclosure. For example, the types, concentration(s) and number of quaternary ammonium compounds may be varied. In some embodiments, alkaline solutions may be interchangeable. Interchangeability may allow solubility enhancing agents to be custom adjusted (e.g., by concentration(s), number of solubility enhancing agents, identity of solubility enhancing agents). In addition, applications of methods, systems, and compositions disclosed herein may be used for treating a wide variety of food products, wherein the food product comprises poultry, pork, beef, seafood, a fruit, a vegetable, or a combination thereof. In addition, the methods, systems, and compositions disclosed herein may be scaled up (e.g., to be used for large scale farming) or down (e.g., to be used for individual or parts of food products) to suit the needs and/or desires of a practitioner. Each disclosed method and method step may be performed in association with any other disclosed method or method step and in any order according to some embodiments. Where the verb “may” appears, it is intended to convey an optional and/or permissive condition, but its use is not intended to suggest any lack of operability unless otherwise indicated. Where open terms such as “having” or “comprising” are used, one of ordinary skill in the art having the benefit of the instant disclosure will appreciate that the disclosed features or steps optionally may be combined with additional features or steps. Such option may not be exercised and, indeed, in some embodiments, disclosed systems, compositions, apparatuses, and/or methods may exclude any other features or steps beyond those disclosed herein. Elements, compositions, devices, systems, methods, and method steps not recited may be included or excluded as desired or required. Persons skilled in the art may make various changes in methods of preparing and using a composition, device, and/or system of the disclosure. For example, a composition, device, and/or system may be prepared and or used as appropriate for animal and/or human use (e.g., with regard to sanitary, infectivity, safety, toxicity, biometric, and other considerations).

Also, where ranges have been provided, the disclosed endpoints may be treated as exact and/or approximations as desired or demanded by the particular embodiment. Where the endpoints are approximate, the degree of flexibility may vary in proportion to the order of magnitude of the range. For example, on one hand, a range endpoint of about 50 in the context of a range of about 5 to about 50 may include 50.5, but not 52.5 or 55 and, on the other hand, a range endpoint of about 50 in the context of a range of about 0.5 to about 50 may include 55, but not 60 or 75. In addition, it may be desirable, in some embodiments, to mix and match range endpoints. Also, in some embodiments, each figure disclosed (e.g., in one or more of the examples, tables, and/or drawings) may form the basis of a range (e.g., depicted value +/− about 10%, depicted value +/− about 50%, depicted value +/− about 100%) and/or a range endpoint. With respect to the former, a value of 50 depicted in an example, table, and/or drawing may form the basis of a range of, for example, about 45 to about 55, about 25 to about 100, and/or about 0 to about 100. Disclosed percentages are weight percentages except where indicated otherwise.

All or a portion of a device and/or system for sanitizing food products with regard to at least one microorganism without substantial residue of antimicrobial composition left on the sanitized food product may be configured and arranged to be disposable, serviceable, interchangeable, and/or replaceable. These equivalents and alternatives along with obvious changes and modifications are intended to be included within the scope of the present disclosure. Accordingly, the foregoing disclosure is intended to be illustrative, but not limiting, of the scope of the disclosure as illustrated by the appended claims.

The title, abstract, background, and headings are provided in compliance with regulations and/or for the convenience of the reader. They include no admissions as to the scope and content of prior art and no limitations applicable to all disclosed embodiments.

### EXAMPLES

### Example 1

### Electroless-Plating of Nickel

A provided polyimide film is subjected to a surface treatment using TAMACLEAN 110 reagent (Arakawa Chemical Industries, Ltd.) at a temperature of 35° C. for about 150 seconds. Then an electroless plating method employing the SLP process developed by Okuno Chemical Industries, Ltd. (including surface charge adjustment, pre-immersion, catalyst and acceleration) is applied to form a three-layer laminate comprised of nickel metal layer/polyimide film/nickel metal layer. The sum of the thickness of the two nickel metal layers is about 0.217 μm. The SLP series reagents including SLP-200, SLP-300, SLP-400, SLP-500 and SLP-600 are purchased from Okuno Chemical Industries, Ltd.

Roll Loosening Treatment

The aforementioned electroless plating of nickel may be conducted according to a roll-to-roll processing method. The roll of the laminate is subjected to a loosening treatment conducted with a coil opening machine (purchased from Cheng-Guang Enterprise).

Thermal Treatment

After it is loosened, the rolled laminate is heated continuously at a temperature of about 90° C. for 12 hours.

Copper Electroplating

Electroplating (the plating solution contains H₂SO₄, CuSO₄, Cl⁻) then is applied to the thermally-treated laminate to form two copper layers on the outer surfaces of the two nickel layers. A flexible metal-clad laminate is thereby obtained.

### Examples 2˜6

A flexible copper-clad laminate is prepared like in Example 1, except that the parameters of the thermal treatment are changed as shown in Table 1.

### Comparative Examples 1˜27

A flexible copper-clad laminate is prepared like in Example 1, except that the parameters of the thermal treatment are changed as shown in Table 1.

### Comparative Example 28

A flexible copper-clad laminate is prepared like in Example 1, except that no thermal treatment is applied.

Testing of Laminate Properties

1. Weight Loss

Before it undergoes a thermal treatment, the laminate comprised of the nickel metal layer/polyimide film/nickel metal layer is cut to obtain a sample having a length of 95 mm and a width of 55 mm. The weight W0 of the sample before thermal treatment is measured with an electronic scale (Cat. No. DENVER TP-214). After completion of the thermal treatment and cooling for about 1 minute, the weight of the sample is measured again, this weight after thermal treatment is designated W1. The weight loss is derived from the following equation:

Weight loss (%)=(W0-W1)/W0×100%

2. Peel strength:

Based on an IPC-TM-650 2.4.9, an initial peel strength P0 of the flexible copper-clad laminate is measured with a single column universal machine (Cat. No. QC-538M1, Cometech Testing Machines Co., Ltd.). The flexible copper-clad laminate then is subjected to an aging treatment at a temperature of 150° C. for 168 hours, after which its peel strength P1 is measured. A peel strength retention then can be derived from the following equation:

Peel strength retention (%)=(P1/P0)×100%.

The results are shown in Table 1.

TABLE 1

| | | | | Peel strength | | |
|---|---|---|---|---|---|---|
| | Thermal treatment | | | P0 | P1 | |
| | Temperature (° C.) | Time (hr) | Weight loss | (kgf/cm) | (kgf/cm) | Retention |
| Comparative Example 1 | 70 | 0.15 | 0.16% | 0.682 | 0.124 | 18.2% |
| Comparative Example 2 | | 2 | 0.62% | 0.673 | 0.142 | 21.1% |
| Comparative Example 3 | | 12 | 0.97% | 0.695 | 0.165 | 23.7% |
| Comparative Example 4 | | 24 | 1.15% | 0.697 | 0.192 | 27.5% |
| Comparative Example 5 | 90 | 0.15 | 0.19% | 0.691 | 0.107 | 15.5% |
| Comparative Example 6 | | 2 | 0.62% | 0.702 | 0.133 | 18.9% |
| Example 1 | | 12 | 1.24% | 0.682 | 0.394 | 57.8% |
| Example 2 | | 24 | 1.37% | 0.696 | 0.438 | 62.9% |
| Comparative Example 7 | | 30 | 1.38% | 0.688 | 0.422 | 61.3% |
| Comparative Example 8 | 110 | 0.15 | 0.32% | 0.709 | 0.130 | 18.3% |
| Comparative Example 9 | | 2 | 0.78% | 0.688 | 0.245 | 35.6% |
| Example 3 | | 12 | 1.41% | 0.702 | 0.495 | 70.5% |
| Example 4 | | 24 | 1.53% | 0.714 | 0.538 | 75.4% |
| Comparative Example 10 | | 30 | 1.52% | 0.696 | 0.504 | 72.4% |
| Comparative Example 11 | 130 | 0.15 | 0.38% | 0.682 | 0.142 | 20.8% |
| Comparative Example 12 | | 2 | 1.09% | 0.703 | 0.346 | 49.2% |
| Example 5 | | 12 | 1.57% | 0.696 | 0.488 | 70.1% |
| Example 6 | | 24 | 1.68% | 0.677 | 0.465 | 68.7% |
| Comparative Example 13 | | 30 | 1.65% | 0.346 | Cannot be | Cannot be |
| | | | | | determined | determined |
| Comparative Example 14 | 150 | 0.15 | 0.46% | 0.669 | 0.133 | 19.9% |
| Comparative Example 15 | | 2 | 1.12% | 0.651 | 0.174 | 26.7% |
| Comparative Example 16 | | 12 | 1.58% | 0.682 | 0.281 | 41.2% |
| Comparative Example 17 | | 24 | 1.67% | 0.670 | 0.255 | 38.1% |
| Comparative Example 18 | | 30 | 1.69% | 0.203 | Cannot be | Cannot be |
| | | | | | determined | determined |
| Comparative Example 19 | 170 | 0.15 | 0.64% | 0.527 | 0.088 | 16.7% |
| Comparative Example 20 | | 2 | 1.25% | 0.430 | 0.056 | 13.0% |
| Comparative Example 21 | | 12 | 1.64% | 0.375 | 0.036 | 9.6% |
| Comparative Example 22 | | 24 | 1.73% | 0.348 | 0.038 | 10.9% |
| Comparative Example 23 | | 30 | 1.75% | 0.168 | Cannot be | Cannot be |
| | | | | | determined | determined |
| Comparative Example 24 | 190 | 0.15 | 0.82% | 0.456 | 0.076 | 16.7% |
| Comparative Example 25 | | 2 | 1.39% | 0.403 | 0.032 | 7.9% |
| Comparative Example 26 | | 12 | 1.73% | 0.347 | 0.036 | 10.4% |
| Comparative Example 27 | | 24 | 1.77% | 0.322 | 0.032 | 9.9% |

| | | | | | |
|---|---|---|---|---|---|
| Comparative Example 28 | None | Not detected | 0.695 | 0.067 | 9.6% |

“Cannot be determined” in Table 1 means that the peel strength between the nickel metal layer and the copper metal layer cannot be determined because at least a part of the flexible metal-clad laminate undergoing the aging treatment exhibits separation between the nickel and copper layers.

Each embodiment disclosed herein has certain unique features. For example, in some embodiments, a laminate having about 50% or more of the peel strength retention may exhibit desirable film properties, e.g., for following processing steps and applications. In some embodiments, compared to laminates not subjected to thermal treatment (e.g., Comparative Example 28), the thermally treated laminates of Examples 1 to 6 may provide better drying effects, which may be observed by a weight loss of about 1% or higher, and can maintain good peel strength. With Comparative Examples 5-6, 8-9 and 11-12, the heating temperature is suitable but the heating time is about 2 hours or less, which may result in insufficient drying of the laminates (less than about 1% of weight loss) and reduction of the peel strength after aging treatment (the peel strength retention is less than about 50%), which may affect the following processing steps and applications of a flexible metal-clad laminate.

Laminates of Comparative Examples 7, 10 and 13 are subjected to heating over a period of time longer than in Examples 1 to 6 (about 28 hours or longer), and exhibit surface oxidation of the nickel layer. For Comparative Examples 7, 10 and 13, a peel strength of the metal-clad laminate cannot be determined after aging treatment (e.g., Comparative Example 13), or a copper plating is affected (i.e., the copper layer may separate from the nickel layer as described hereinafter).

According to some embodiments, thermal treatment may be conducted within a suitable temperature range. In some embodiments, if a heating temperature is too low (e.g., as shown with Comparative Examples 1 to 4), no desirable peel strength retention may be obtained, even if heating were conducted over a relatively long period of time. The testing results for the laminates of Comparative Examples 14 to 27 show that regardless the heating time, rapid water vaporization and volume expansion of a laminate may be caused by a relatively high heating temperature (e.g., 150° C. or more), which breaks the interface of a nickel layer. Therefore, even if drying occurs, the peel strength of laminates may reduce to as low as that of a laminate without thermal treatment (e.g., Comparative Example 28).

According to some embodiments, the quality of the flexible metal-clad laminates obtained with the above examples and comparative examples may be determined as follows. The flexible metal-clad laminates of Examples 1-6 may have higher thermal stability than flexible metal-clad laminates of Comparative Examples 1-6, 8-9, 11-12, 14-17, 19-22, 24-28. Separation may occur between a nickel layer and a copper layer in the flexible metal-clad laminates of Comparative Examples 7, 10, 13, 18, 23. Moreover, a testing results show that when a thermal treatment exceeds 28 hours, a nickel layer may be subjected to surface oxidation that weakens the adhesion between a nickel and a copper layers, which may increase the risk of layer separation, leading to undesirable laminate products. On the other hand, when the heating time is excessively long, the laminate may be not uniformly etched by a copper sulfate solution during copper electroplating, which causes reduced yield and defects in the appearance, color and copper thickness of the flexible metal-clad laminates.

Testing conducted for the aforementioned examples and comparative examples shows that a thermal treatment applied on the laminates may have an impact on the stability of peel strength. Moreover, thermal treatment may be performed within a particular temperature range and for a certain period of time in order to obtain desirable effects.

Further, the thickness of a nickel metal layer may have an impact in the fabrication of the flexible metal-clad laminate, which is shown by the following testing of examples and comparative examples.

### Example 7

A flexible metal-clad laminate is prepared like in Example 1, except that the total thickness of the two nickel metal layers is 0.186 μm and the thermal treatment is conducted at a temperature of 120° C. for 24 hours. Then the laminate is subjected to roll-to roll copper electroplating. The laminate (including a polyimide layer and two nickel layers at two opposite sides thereof) is pulled out from a cylindrical roll, and fed into an electroplating tank to form two copper layers on the outer surfaces of the two nickel layers. The electroplating tank contains a first electroplating zone and a second electroplating zone. The first electroplating zone uses a plating solution containing 200 g/L H₂SO₄, 55 g/L CuSO₄ and 50 ppm Cl⁻, and is applied with a current density of 2 ASD. The second electroplating zone uses a plating solution containing 150 g/L H₂SO₄, 120 g/L CuSO₄ and 50 ppm Cl⁻, and is applied with a current density of 4 ASD. A total copper thickness (i.e., sum of the thickness of the two copper layers formed on the two nickel layers) thereby formed is about 5 μm. The metal-clad laminate thereby formed is collected and wound to form a cylindrical roll.

### Examples 8˜10

A flexible copper-clad laminate is prepared like in Example 7, except that a sum of the thickness of the two nickel layers is changed as shown in Table 2.

### Comparative Examples 29˜32

A flexible copper-clad laminate is prepared like in Example 7, except that a sum of the thickness of the two nickel layers is changed as shown in Table 2.

Testing of Film Properties

1. Weight loss: as previously described.

2. Peel strength: as previously described.

3. Surface resistance:

Based on JIS K7194, a surface resistance of an intermediate laminate comprised of nickel layer/polyimide film/nickel layer is measured with a surface low resistance meter (Cat. No. MCP-T610, Mitsubishi Chemical Analytech Co., LTD.) having a four-point probe.

The results are shown in Table 2.

TABLE 2

| | | | | Peel Strength | | | |
|---|---|---|---|---|---|---|---|
| | Total thickness of both | Surface | | P0 | P1 | | RTR copper |
| | nickel layers (μm) | Resistance (Ω/sq) | Weight Loss | (kgf/cm) | (kgf/cm) | Retention | electroplating |
| Comparative Example 29 | 0.090 | 8.53 | 1.77% | 0.687 | 0.446 | 64.9% | x |
| Comparative Example 30 | 0.145 | 6.05 | 1.70% | 0.658 | 0.448 | 68.1% | Δ |
| Example 7 | 0.186 | 5.22 | 1.62% | 0.696 | 0.532 | 76.4% | ∘ |
| Example 8 | 0.217 | 4.38 | 1.66% | 0.708 | 0.553 | 78.1% | ∘ |
| Example 9 | 0.242 | 3.25 | 1.65% | 0.686 | 0.516 | 75.2% | ∘ |
| Example 10 | 0.276 | 3.06 | 1.58% | 0.693 | 0.482 | 69.6% | ∘ |
| Comparative Example 31 | 0.304 | 2.92 | 1.36% | 0.701 | 0.347 | 49.5% | ∘ |
| Comparative Example 32 | 0.322 | 2.47 | 1.24% | 0.679 | 0.305 | 44.9% | ∘ |

In Table 2, the symbol “x” means that electroplating cannot be performed; the symbol “Δ” means that operability of the electroplating is acceptable; and the symbol “∘” means that operability of the electroplating is good.

Each embodiment disclosed herein has certain unique features. For example, in some embodiments, copper electroplating may not have been successfully conducted in embodiments such as Comparative Example 29, because each nickel layer is thin: during electroplating of copper, each thin nickel layer is dissolved in the copper sulfate solution or burns owing to its high resistance. In some embodiments, with respect to Comparative Example 30, copper electroplating conditions may have to be monitored and may require manual adjustment of the applied voltage, and the roll-to-roll production speed may need to be reduced. In some embodiments, a good operability in the remaining examples may mean that the roll-to-roll production is fully automatic and the production speed is not affected.

In some embodiments, as illustrated in Table 2, when the sum of the thickness of the two nickel layers is small (e.g., as in Comparative Examples 29 and 30), water may be easily removed by the thermal treatment, but the roll-to-roll copper electroplating process may be difficult to accomplish due to poor conductivity and easy dissolution of thin nickel layers. According to some embodiments, when the sum of the thickness of two nickel layers is excessively high (e.g., as in Comparative Examples 31 and 32), a thermal treatment may be insufficient, which can adversely affect the peel strength retention that cannot reach 50%. Examples 7-10 may show laminates having added thicknesses of the two nickel layers that may offer peel strength stability and operability, and maintain a yield of a roll-to-roll copper electroplating process, which may be advantageous to large-scale manufacturing.

According to some embodiments, methods described herein may induce a cost reduction, an easy operation, and a high product yield. In some embodiments, the methods dmay produce a flexible metal-clad laminates with improved thermal stability, a good interlayer adhesion (i.e., high peel strength), an anti-hygroscopicity, an aging resistance, an easy etching, a light product, and a thin product. These features may benefit applications of flexible metal-clad laminates such as packaging material, encapsulating material, and the like.

What is claimed is:

1. A method of fabricating a flexible metal-clad laminate, the method comprising:
forming a metal layer on a surface of a polyimide film, wherein the metal layer and the polyimide film contacting with each other and forming a laminate; and
heating the laminate at a temperature of about 80° C. to about 140° C. until a weight loss of the laminate reaches about 1% or higher.

2. The method according to claim 1, wherein the metal layer comprises a nickel layer formed by electroless plating, wherein the nickel layer thickness is about 0.05 μm to about 0.15 μm.

3. The method according to claim 1, wherein before forming the metal layer, the method further includes performing a surface treatment on the polyimide film, the surface treatment comprising an alkali surface modification, a charge adjustment, a catalyst treatment, and an activating treatment.

4. The method according to claim 3, wherein the catalyst treatment and the activating treatment forms a palladium catalyst on the surface of the polyimide film.

5. The method according to claim 1, wherein the step of heating the laminate is performed at a temperature of about 90° C. to about 130° C.

6. The method according to claim 1, wherein heating the laminate is performed continuously for less than about 28 hours.

7. The method according to claim 1, wherein the weight loss is about 1% to about 2%.

8. The method according to claim 1, wherein a peel strength retention between the polyimide film and the metal layer is about 50% or higher, the peel strength retention being derived from the following equation:
peel strength retention (%)=(P1/P0)×100%,
wherein P0 is an initial peel strength before heating the laminate, and P1 is a peel strength after heating the laminate and an aging treatment at a temperature of about 150° C. for about 168 hours.

9. The method according to claim 1, wherein the polyimide film comprises a plurality of microvias.

10. The method according to claim 1, further comprises forming a copper layer on the metal layer by electroplating after the heating step.

11. The method according to claim 10, wherein the copper layer comprises a first copper sublayer formed with a first electroplating, and a second copper sublayer formed with a second electroplating.

12. The method according to claim 11, wherein a thickness ratio of the first copper sublayer to a sum of a thickness of the first copper sublayer and the second copper sublayer is about 20% or higher.

13. A method of fabricating a flexible metal-clad laminate, the method comprising:
forming a metal layer on a surface of a polyimide film according to a roll-to-roll processing technique, wherein the metal layer and the polyimide film are contacting each other and forming a rolled laminate;
loosening the rolled laminate to form gaps between adjacent coils in the rolled laminate; and
heating the rolled laminate at a temperature of about 80° C. to about 140° C. until a weight loss of the rolled laminate reaches about 1% or higher.

14. The method according to claim 13, wherein the metal layer is a nickel layer formed by electroless plating, the nickel layer having a thickness of about 0.05 μm to about 0.15 μm.

15. The method according to claim 13, wherein before forming the metal layer, the method further comprises applying a surface treatment on the polyimide film, the surface treatment comprises an alkali surface modification, a charge adjustment, a catalyst treatment, and an activating treatment.

16. The method according to claim 15, wherein the catalyst treatment and the activating treatment are performed to form a palladium catalyst on the surface of the polyimide film.

17. The method according to claim 13, wherein the step of heating the rolled laminate is performed at a temperature of about 90° C. to about 130° C.

18. The method according to claim 13, wherein heating the rolled laminate is performed continuously for less than about 28 hours.

19. The method according to claim 13, wherein the weight loss is about 1% to about 2%.

20. The method according to claim 13, wherein a peel strength retention between the polyimide film and the metal layer is about 50% or higher, the peel strength retention being derived from the following equation:
peel strength retention (%)=(P1/P0)×100%
wherein P0 is an initial peel strength before heating the laminate, and P1 is a peel strength after heating the laminate and an aging treatment at a temperature of about 150° C. for about 168 hours.

21. The method according to claim 13, further comprising forming a copper layer on the metal layer by electroplating after heating the laminate.

22. The method according to claim 21, wherein the copper layer comprises a first copper sublayer formed with a first electroplating, and a second copper sublayer formed with a second electroplating.

23. The method according to claim 22, wherein a thickness ratio of the first copper sublayer to a sum of a thickness of the first copper sublayer and the second copper sublayer is about 20% or higher.

24. The method according to claim 13, wherein the rolled laminate is placed in a vertically upright position while heating the rolled laminate.
